(19) United States
(12) Patent Application Publication
(10) Pub. No.: US 2019/0221533 A1
(43) Pub. Date: Jul. 18, 2019

(54) SEMICONDUCTOR DEVICES COMPRISING METALLIZATIONS COMPOSED OF POROUS COPPER AND ASSOCIATED PRODUCTION METHODS

(71) Applicant: Infineon Technologies AG, Neubiberg (DE)

(72) Inventors: Horst THEUSS, Wenzenbach (DE); Rudolf BERGER, Regensburg (DE); Walter HARTNER, Bad Abbach-Peissing (DE); Veronika HUBER, Bad Abbach (DE); Werner ROBL, Regensburg (DE)

(73) Assignee: Infineon Technologies AG, Neubiberg (DE)

(21) Appl. No.: 16/246,912

(22) Filed: Jan. 14, 2019

(30) Foreign Application Priority Data
Jan. 16, 2018 (DE) 102018100843.0

(51) Int. Cl. H01L 23/00; H01L 23/498; H01L 21/48

(52) U.S. Cl. CPC H01L 24/05; H01L 2924/3512; H01L 23/49866; H01L 23/49838; H01L 23/49822; H01L 23/49827; H01L 24/03; H01L 24/81; H01L 21/4857; H01L 21/486; H01L 24/13; H01L 2224/05647; H01L 2224/0401; H01L 2224/13147; H01L 2224/0239; H01L 2224/03462; H01L 2224/03848; H01L 2224/0231; H01L 2224/16227; H01L 2224/13024; H01L 2224/13023; H01L 24/16

(57) ABSTRACT

A semiconductor device includes a semiconductor chip, an electrical connection element for electrically connecting the semiconductor device to a carrier, and a metallization adjoining the electrical connection element, the metallization contains porous nanocrystalline copper that contains portions of organic acids.

### FIELD

The present disclosure relates generally to semiconductor technology. In particular, the disclosure relates to semiconductor devices that include metallizations composed of porous copper and methods for producing such semiconductor devices.

### BACKGROUND

A critical parameter in the production of semiconductor packages is Temperature Cycling on Board (TCoB), which involves testing the ability of components and soldering connections of the semiconductor packages to withstand mechanical stress triggered by temperature cycles. By way of example, defects in the form of cracks and increased electrical resistance can occur after a plurality of temperature cycles. A continuous increase in the integration level during the development of new products leads to an increase in the package size and thus to reduced TCoB performance of the semiconductor devices produced. Manufacturers of semiconductor devices therefore endeavor to provide semiconductor devices having improved TCoB performance and methods for producing such semiconductor devices.

### SUMMARY

Various aspects relate to a semiconductor device, including a semiconductor chip, an electrical connection element for electrically connecting the semiconductor device to a carrier, and a metallization adjoining the electrical connection element, wherein the metallization contains porous nanocrystalline copper.

In general, the semiconductor chip can contain integrated circuits, passive electronic components, active electronic components, etc. The integrated circuits can be configured as integrated logic circuits, analog integrated circuits, integrated mixed-signal circuits, integrated power circuits, etc. In one example, the semiconductor chip can be produced from an elemental semiconductor material, for example Si, etc. In a further example, the semiconductor chip can be produced from a compound semiconductor material, for example GaN, SiC, SiGe, GaAs, etc. The semiconductor chip can have one or more electrical contacts in the form of contact pads or contact electrodes, which can be arranged in particular on a main surface of the semiconductor chip.

The electrical connection element can include solder material. In one example, the connection element can be a solder ball. However, the connection element is not restricted to a specific geometric shape. The connection element can therefore also more generally be a solder deposit, a solder coating, a solder bead or a solder bump. By way of example, the connection element can be one of a plurality of solder balls on main surfaces of flip-chip packages or ball grid arrays, by means of which these can be soldered onto a circuit board.

In comparison with standard copper used in the production of semiconductor devices, porous copper can build up far less mechanical stress 6 with comparable mechanical strain E. As a result, by way of example, a mechanical stress that is produced during TCoB or occurs during operation of the device can be significantly reduced. In comparison with standard copper, porous copper furthermore exhibits a higher reversible strain, a lower flow stress, a lower modulus of elasticity, a greater mean roughness and a reduced electrical conductivity. The terms “porous nanocrystalline copper” and “porous copper” can be used synonymously or interchangeably in this description.

In accordance with one embodiment, the porous nanocrystalline copper contains portions of organic acids. In particular, the porous nanocrystalline copper can contain portions of citric acid.

In accordance with one embodiment, the porosity of the porous nanocrystalline copper lies in a range of 5% to 20%, in particular in a range of approximately 9.3% to approximately 12.7%. In this case, the porosity is a dimensionless variable and corresponds to the ratio of cavity volume to total volume of the porous copper or of the body formed therefrom.

In accordance with one embodiment, the mean (arithmetic mean) pore diameter of the porous nanocrystalline copper is less than 1 μm. Furthermore, the pore size of the porous nanocrystalline copper can be less than approximately 0.79 μm². In this case, the pore size can be specified as the cross-sectional area of the cavity formed by the respective pore and thus have the dimension of an area. An exemplary relative pore distribution for porous copper as a function of the pore size of the copper is shown in FIG. 13.

In accordance with one embodiment, the metallization has a closed-porous region extending at the surface of the metallization. The porous copper described herein can thus be a closed-porous material having no open pores at its surface. This property can differentiate the porous copper described herein from other types of porous copper that have open pores at their surface. On account of its closed-porous property, the porous copper described herein can form a protective layer that prevents harmful gases and liquids from being able over time to penetrate into a body formed by the porous copper (e.g. a contact) and from impairing the electrical effect of the body (e.g. of the contact). Furthermore, on account of its closed-porous property, the porous copper can be coatable, i.e. a coating is deposited only on the surface of the copper, but does not penetrate into the interior of the copper. By way of example, tin plating or soldering on a metallization formed by the porous copper becomes possible as a result.

In accordance with one embodiment, the metallization is part of a contact pad of the semiconductor chip and the electrical connection element is arranged on the contact pad.

In accordance with one embodiment, the metallization is part of a underbump metallization arranged between a contact pad of the semiconductor chip and the electrical connection element. The underbump metallization can be arranged e.g. below an electrical connection element composed of solder material (solder bump) and provide an electrical connection between the contact pad of the semiconductor chip and the electrical connection element. In this context, the underbump metallization can also prevent an undesired diffusion of solder material into the semiconductor chip. In particular, it is possible to use underbump metallizations in semiconductor packages with electrical connection elements in the form of solder balls, for example in flip-chip packages or ball grid arrays. An underbump metallization can be produced for example from at least one of the following metals and associated alloys: aluminum, nickel, copper.

In accordance with one embodiment, the metallization is part of a copper pillar arranged on the semiconductor chip, said copper pillar being arranged between a contact pad of the semiconductor chip and the electrical connection element. The copper pillar can be part of an electrical connection element in the form of a copper pillar bump constructed from the in particular cylindrical copper pillar and a cap of solder material arranged thereon. Connection elements of this type can be used for example in the case of a flip-chip contacting.

In accordance with one embodiment, the metallization is part of a conductor track of a redistribution layer arranged on the semiconductor chip, wherein the redistribution layer is electrically connected to the electrical connection element. The conductor track can be one of a plurality of conductor tracks in the form of metal layers or metal tracks that can be arranged above a main surface of a semiconductor chip. In this case, the conductor tracks can extend laterally beyond the main surface of the semiconductor chip or beyond other materials such as dielectric layers, for example, which are arranged between the semiconductor chip and the conductor tracks. The conductor tracks can be used as a redistribution layer in order to electrically couple contact elements of the semiconductor chips to external contact elements of the device, such as solder bumps, for example. In other words, the conductor tracks can be designed to make I/O contact areas of the semiconductor chip available at other positions of the device. In one example, such a redistribution layer can be used in a fan-out type semiconductor package. A multiplicity of dielectric layers can be arranged between the multiplicity of conductor tracks in order to electrically insulate the conductor tracks from one another. Furthermore, metal layers arranged on different planes can be electrically connected to one another by a multiplicity of plated-through holes (or vias).

In accordance with one embodiment, the carrier has a first main surface and a second main surface situated opposite the first main surface, wherein the semiconductor chip is arranged on the first main surface of the carrier and the electrical connection element is arranged on the second main surface of the carrier.

In accordance with one embodiment, the metallization is part of a conductor track of a redistribution layer within the carrier, wherein the redistribution layer is electrically connected to the electrical connection element. Besides the use, already described above, of a redistribution layer arranged on a semiconductor chip, redistribution layers can also be arranged within a carrier or within a circuit board. In this case, the associated metal layers or conductor tracks of the redistribution layer can have the function, in particular, of electrically coupling contact elements on one main surface of the carrier or the circuit board to contact elements on an opposite main surface of the carrier or the circuit board.

In accordance with one embodiment, the metallization is part of a plurality of metallization planes of a redistribution layer within the carrier.

In accordance with one embodiment, the metallization is part of a conductor track on one of the main surfaces of the carrier, wherein the conductor track is electrically connected to the electrical connection element.

In accordance with one embodiment, the metallization is part of a via connection within the carrier.

Various aspects relate to a method for producing a metallization in a semiconductor device. The method includes electrochemical deposition of copper, and heat treatment of the deposited copper, as a result of which a metallization composed of porous nanocrystalline copper is formed.

In accordance with one embodiment, an electrolyte used for the electrochemical deposition includes copper sulfate, ammonium sulfate and citric acid.

In accordance with one embodiment, an electrolyte used for the electrochemical deposition has a pH of 1.8 to 2.5.

In accordance with one embodiment, a current density used for the electrochemical deposition lies in a range from 0.5 A/dm² to 6 A/dm².

Various aspects relate to a semiconductor device including a circuit board, a semiconductor component arranged on the circuit board, and an electrical connection element, wherein the electrical connection element is electrically connected to the circuit board. Furthermore, the semiconductor device includes a metallization of the circuit board adjoining the electrical connection element, wherein the metallization contains porous nanocrystalline copper.

In accordance with one embodiment, the metallization is part of a conductor track or of a via connection of a redistribution layer within the circuit board, wherein the redistribution layer is electrically connected to the electrical connection element.

### BRIEF DESCRIPTION OF THE DRAWINGS

The accompanying drawings serve to deepen the understanding of aspects of the present disclosure. The drawings illustrate embodiments and together with the description serve to elucidate the principles of these aspects. The elements of the drawings need not necessarily be true to scale relative to one another. Identical reference signs designate corresponding similar parts.

FIG. 1 schematically shows a lateral cross-sectional view of a semiconductor device 100 in accordance with the disclosure.

FIG. 2 schematically shows a lateral cross-sectional view of a semiconductor device 200 in accordance with the disclosure.

FIG. 3 shows a flow diagram of a method for producing a metallization in a semiconductor device in accordance with the disclosure.

FIG. 4 schematically shows a lateral cross-sectional view of a semiconductor device 400 in accordance with the disclosure. The semiconductor device 400 contains a contact pad of a semiconductor chip, said contact pad comprising porous nanocrystalline copper.

FIG. 5 schematically shows a lateral cross-sectional view of a semiconductor device 500 in accordance with the disclosure. The semiconductor device 500 contains an underbump metallization comprising porous nanocrystalline copper.

FIG. 6 schematically shows a lateral cross-sectional view of a semiconductor device 600 in accordance with the disclosure. The semiconductor device 600 contains a redistribution layer with a conductor track comprising porous nanocrystalline copper.

FIG. 7 schematically shows a lateral cross-sectional view of a semiconductor device 700 in accordance with the disclosure. The semiconductor device 700 contains a copper pillar comprising porous nanocrystalline copper.

FIG. 8 schematically shows a lateral cross-sectional view of a semiconductor device 800 in accordance with the disclosure. The semiconductor device 800 contains a circuit board/carrier comprising porous nanocrystalline copper.

FIG. 9 schematically shows a lateral cross-sectional view of a semiconductor device 900 in accordance with the disclosure. The semiconductor device 900 is a ball grid array (BGA), which can contain for example one of the structures comprising porous nanocrystalline copper that are shown in FIGS. 4 to 8.

FIG. 10 contains FIGS. 10A to 10C and schematically illustrates lateral cross-sectional views of semiconductor devices 1000A to 1000C in accordance with the disclosure. The semiconductor devices 1000A to 1000C are wafer level packages, each of which can contain one of the structures comprising porous nanocrystalline copper that are illustrated in FIGS. 4 to 7.

FIG. 11 schematically shows a lateral cross-sectional view of a semiconductor device 1100 in accordance with the disclosure. The semiconductor device 1100 comprises a semiconductor component arranged on a circuit board and can contain one of the structures comprising porous nanocrystalline copper that are illustrated in FIGS. 4 to 8.

FIG. 12 shows a temperature-time diagram for a heat treatment process that can be used in the method in FIG. 3 for producing a metallization in a semiconductor device in accordance with the disclosure.

FIG. 13 shows a relative pore distribution for porous nanocrystalline copper such as can be used in one of the semiconductor devices in accordance with the disclosure, as a function of the pore size of the copper.

### DETAILED DESCRIPTION

In the following detailed description, reference is made to the accompanying drawings, which show for illustration purposes specific aspects and embodiments in which the disclosure can be implemented in practice. In this context, direction terms such as, for example, “at the top”, “at the bottom”, “at the front”, “at the back”, etc. can be used with respect to the orientation of the figures described. Since the components of the embodiments described can be positioned in different orientations, the direction terms can be used for illustration purposes and are not restrictive in any way whatsoever. Other aspects can be used and structural or logical changes can be made, without departing from the concept of the present disclosure. That is to say that the following detailed description should not be interpreted in a restrictive sense.

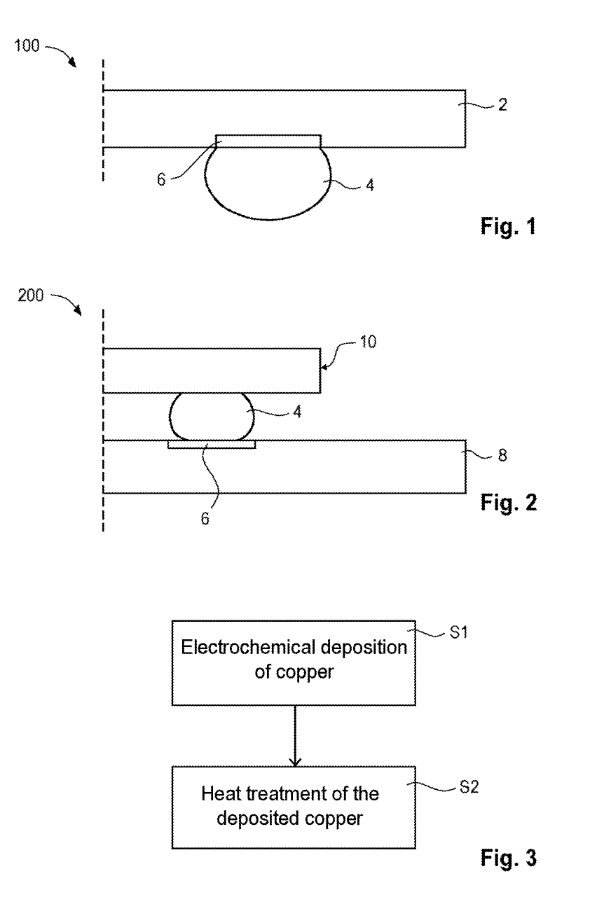

FIG. 1 schematically shows a cross-sectional view of a semiconductor device 100 in accordance with the disclosure. The semiconductor device 100 is illustrated in a general way in order to qualitatively specify aspects of the disclosure. The semiconductor device 100 can contain further components that are not illustrated for the sake of simplicity. By way of example, the semiconductor device 100 can be extended by any of the aspects described in conjunction with other devices in accordance with the disclosure.

The semiconductor device 100 contains a semiconductor chip 2 and an electrical connection element 4 composed e.g. of solder material for electrically connecting the semiconductor device 100 to a carrier (not illustrated). The entire semiconductor chip 2 is not illustrated in the example in FIG. 1, this being indicated by a vertical dashed line on the left. In the illustration chosen, only one electrical connection element 4 is shown, wherein it goes without saying that the semiconductor device can have any desired number of further electrical connection elements. Furthermore, the electrical connection element 4 in FIG. 1 is illustrated in the shape of a ball. However, the geometric shape of the electrical connection element 4 shown is not restrictive and can be chosen differently in further examples. The semiconductor device 100 furthermore comprises a metallization 6 adjoining the connection element 4 composed of solder material, wherein the metallization 6 contains porous nanocrystalline copper. In the example in FIG. 1, the connection element 4 and the metallization 6 directly contact one another. In further examples, a metallization may adjoin a connection element but not necessarily directly touch the latter. In this sense, the term “adjoining” used herein may for example also be replaced by the terms “adjacent” or “in direct proximity”.

The semiconductor device 100 can be soldered onto a carrier or a circuit board (not illustrated) for example by means of the connection element 4 composed of solder material. During operation, in the event of temperature fluctuations, on account of different coefficients of thermal expansion of the components (e.g. of the semiconductor chip 2 and of the circuit board), mechanical stresses can then occur which can result in cracks of the electrical connection element 4 or else of the metallization 6, as is evident from corresponding TCoB results. The metallization 6 can be for example a contact pad of the semiconductor chip 2, said contact pad being produced from standard copper in conventional semiconductor devices. In comparison with such a standard copper, however, the nanocrystalline porous copper used in accordance with the disclosure can build up far less mechanical stress 6 with comparable mechanical strain E. As a result, the mechanical stresses mentioned and the instances of cracking associated therewith can be avoided or at least reduced. In each of the examples described herein, such cracking can be avoided or reduced by the use of a metallization comprising porous copper adjoining an electrical connection element.

FIG. 2 schematically shows a cross-sectional view of a semiconductor device 200 in accordance with the disclosure. The semiconductor device 200 is illustrated in a general way in order qualitatively to specify aspects of the disclosure. The semiconductor device 200 can contain further components that are not illustrated for the sake of simplicity. By way of example, the semiconductor device 200 can be extended by any of the aspects described in conjunction with other devices in accordance with the disclosure.

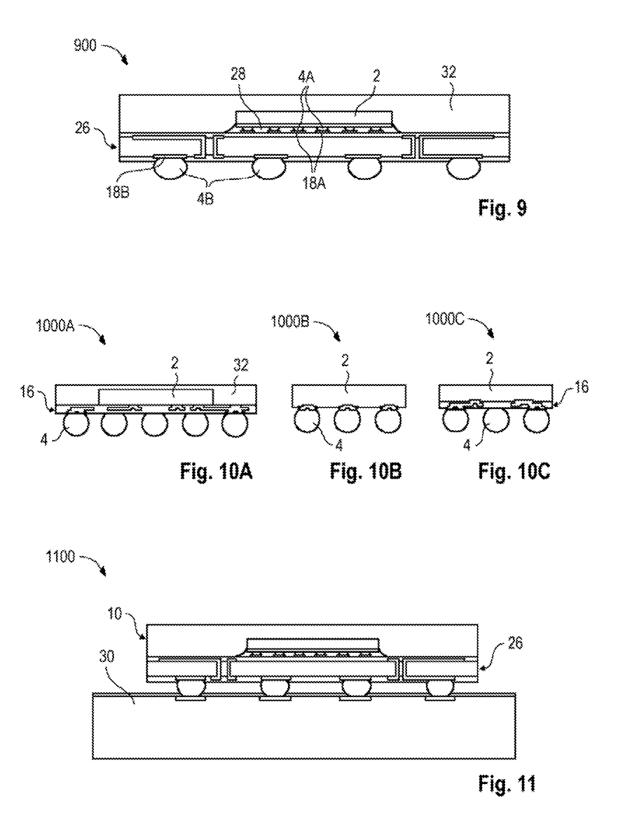

The semiconductor device 200 contains a circuit board 8 and a semiconductor component 10 arranged on the circuit board 8. The circuit board 8 and the semiconductor component 10 are not completely illustrated in the example in FIG. 2, this being indicated by a vertical dashed line on the left. The semiconductor component 10 can be, for example, one of the devices illustrated in FIGS. 9 to 11. The semiconductor device 200 furthermore contains an electrical connection element 4, which can comprise e.g. solder material, wherein the electrical connection element 4 is electrically connected to the circuit board 8. Furthermore, a metallization 6 of the circuit board 8 adjoining the electrical connection element 4 is present, wherein the metallization 6 contains porous nanocrystalline copper. Owing to a use of the porous copper, the semiconductor device 200 can have advantageous properties similar to those such as have already been described in conjunction with FIG. 1. It goes without saying that the arrangement shown in FIG. 2 can also be combined with the arrangement shown in FIG. 1. In this case, both the metallization on the circuit board 8 and the metallization on the semiconductor device comprise porous nanocrystalline copper.

FIG. 3 shows a flow diagram of a method for producing a metallization in a semiconductor device in accordance with the disclosure.

In S1, copper is deposited electrochemically, wherein the deposited copper can be obtained by a cathode reaction Cu²⁺+2e⁻->Cu. Accordingly, a surface on which the copper is deposited during the deposition process can function as cathode. An electrolyte used for the electrochemical deposition can contain copper sulfate (CuSO₄) having an exemplary concentration c(CuSO₄.5H₂O) of approximately 50 g/l to approximately 200 g/l, in particular approximately 100 g/l. Furthermore, the electrolyte can contain ammonium sulfate ((NH₄)₂SO₄) having an exemplary concentration c((NH₄)₂SO₄) of approximately 25 g/l to approximately 100 g/l, in particular approximately 50 g/l. Furthermore, the electrolyte can contain an organic acid, in particular citric acid (C₆H₈O₇), having an exemplary concentration C(C₆H₈O₇) of approximately 2.5 g/l to approximately 10 g/l, in particular approximately 5 g/l. The growth of copper grains can be suppressed by the citric acid added to the electrolyte. On account of the electrolyte used, the metallization ultimately produced can contain portions of citric acid. The electrolyte used for the electrochemical deposition can have a pH of approximately 1.8 to approximately 2.5. A current density used for the electrochemical deposition can lie in a range of approximately 0.5 A/dm² to approximately 6 A/dm².

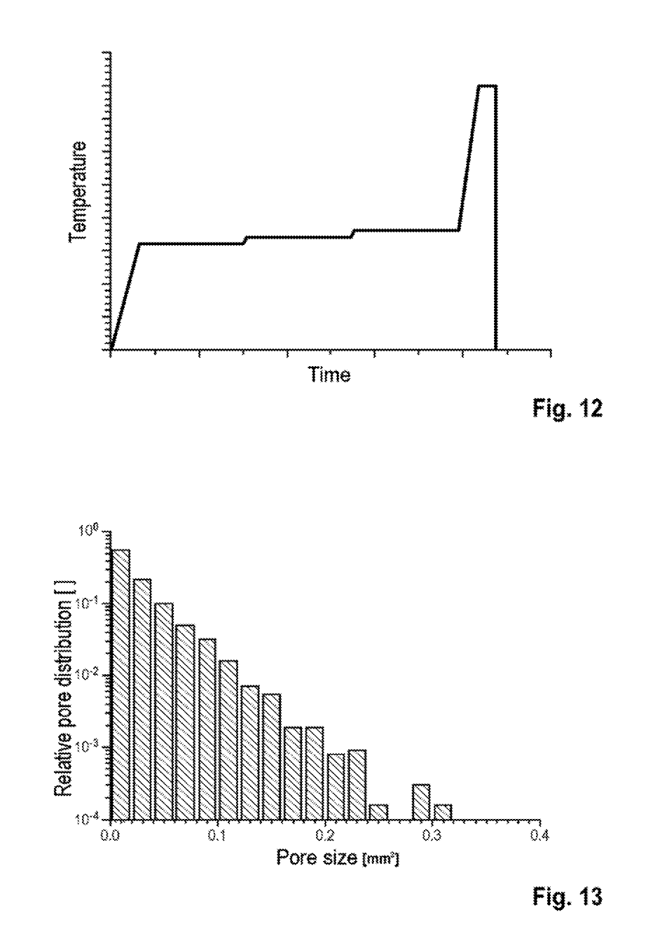

In S2, the deposited copper is subjected to heat treatment, as a result of which a metallization composed of porous nanocrystalline copper is formed. A temperature-time diagram of an exemplary heat treatment process is shown in FIG. 12. The porous copper can have one or more of the properties already described above.

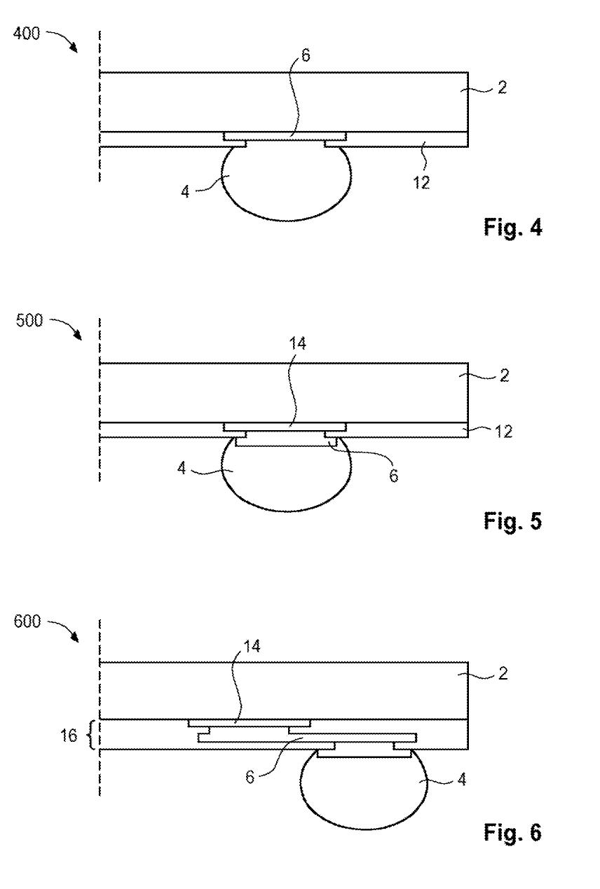

FIG. 4 schematically shows a lateral cross-sectional view of a semiconductor device 400 in accordance with the disclosure. Not all the components of the semiconductor device 400 are completely illustrated in the example in FIG. 4, this being indicated by a vertical dashed line on the left. The semiconductor device 400 contains a semiconductor chip 2 and a metallization 6 in the form of a contact pad, said metallization being arranged on the underside of the semiconductor chip 2. The contact pad 6 can provide an electrical connection to internal circuits of the semiconductor chip 2. The contact pad 6 can be at least partly embedded in a passivation layer 12 that terminates the lower surface of the semiconductor chip 2.

There is arranged on the contact pad 6 an electrical connection element 4 composed of a solder material, which is electrically connected to the contact pad 6 and can thus likewise provide an electrical connection to the internal circuits of the semiconductor chip 2. The solder material of the electrical connection element 4 can be designed, in particular, to electrically and/or mechanically connect the semiconductor device 400 to a carrier or a circuit board (not illustrated). In the example in FIG. 4, the contact pad 6 can be produced from porous nanocrystalline copper or at least proportionally contain the latter.

FIG. 5 schematically shows a lateral cross-sectional view of a semiconductor device 500 in accordance with the disclosure. Not all the components of the semiconductor device 500 are completely illustrated in the example in FIG. 5, this being indicated by a vertical dashed line on the left. The semiconductor device 500 can comprise the already described components of the semiconductor device 400 from FIG. 4. In addition, the semiconductor device 500 can contain a metallization 6 in the form of an underbump metallization between a contact pad 14 and an electrical connection element 4. In the example in FIG. 5, the underbump metallization 6 can be produced from porous nanocrystalline copper or at least proportionally contain the latter. In a further example, the contact pad 14 can likewise comprise porous nanocrystalline copper.

FIG. 6 schematically shows a lateral cross-sectional view of a semiconductor device 600 in accordance with the disclosure. Not all the components of the semiconductor device 600 are completely illustrated in the example in FIG. 6, this being indicated by a vertical dashed line on the left. The semiconductor device 600 can comprise the components of the semiconductor devices 400 and 500 from FIGS. 4 and 5. In addition, the semiconductor device 600 can comprise a redistribution layer 16 with a metallization 6 in the form of a conductor track, said redistribution layer being arranged over the lower main surface of the semiconductor chip 2. In further examples, the redistribution layer 16 can comprise a plurality of metallizations or conductor tracks, which can be electrically insulated from one another by dielectric layers. The conductor track 6 can provide an electrical connection between the contact pad 14 of the semiconductor chip 2 and the electrical connection element 4. Owing to the use of the redistribution layer 16, the electrical connection element 4 thus need not be arranged directly over the contact pad 14.

In the example in FIG. 6, the electrical connection element 4 is arranged over the semiconductor chip 2. In a further example, the semiconductor device 600 can furthermore comprise an encapsulation material (not illustrated), which can cover the side surfaces of the semiconductor chip 2. In this case, the redistribution layer 16 can extend beyond the side surfaces of the semiconductor chip 2, such that the electrical connection element 4 can be arranged over the encapsulation material. In other words, in this further example, the semiconductor device can be a fan-out package. In the example in FIG. 6, the metallization or the conductor track 6 can be produced from porous nanocrystalline copper or at least proportionally contain the latter. In a further example, the contact pad 14 can likewise comprise porous nanocrystalline copper.

In the example in FIG. 6 and in particular in the case of a fan-out package, the method according to which the semiconductor device was produced is unimportant. In a first example, the semiconductor device can be produced by a so-called “die-first, face-down” method, in which first the semiconductor chip (“die-first”) is positioned on a carrier, wherein the contact pads of the semiconductor chip face the carrier (“face-down”). In further steps, the semiconductor chip is embedded into an encapsulation material, the carrier is removed and a redistribution layer is formed over the contact pads of the semiconductor chip. In a second example, the semiconductor device can be produced by a so-called “die-first, face-up” method, in which first the semiconductor chip (“die-first”) is positioned on a carrier, wherein the contact pads of the semiconductor chip face away from the carrier (“face-up”). In further steps, the semiconductor chip is embedded into an encapsulation material, the contact pads of the semiconductor chip are freed of the encapsulation material and a redistribution layer is formed over the contact pads of the semiconductor chip. In a third example, the semiconductor device can be produced by a so-called “die-last, face-down” method, in which first a redistribution layer is formed on a carrier and only afterward is the semiconductor chip (“die-last”) positioned on the carrier or the redistribution layer, wherein the contact pads of the semiconductor chip face the carrier (“face-down”). In further steps, the semiconductor chip is embedded into an encapsulation material, the carrier is removed and external connection elements (e.g. solder balls) are connected to the redistribution layer.

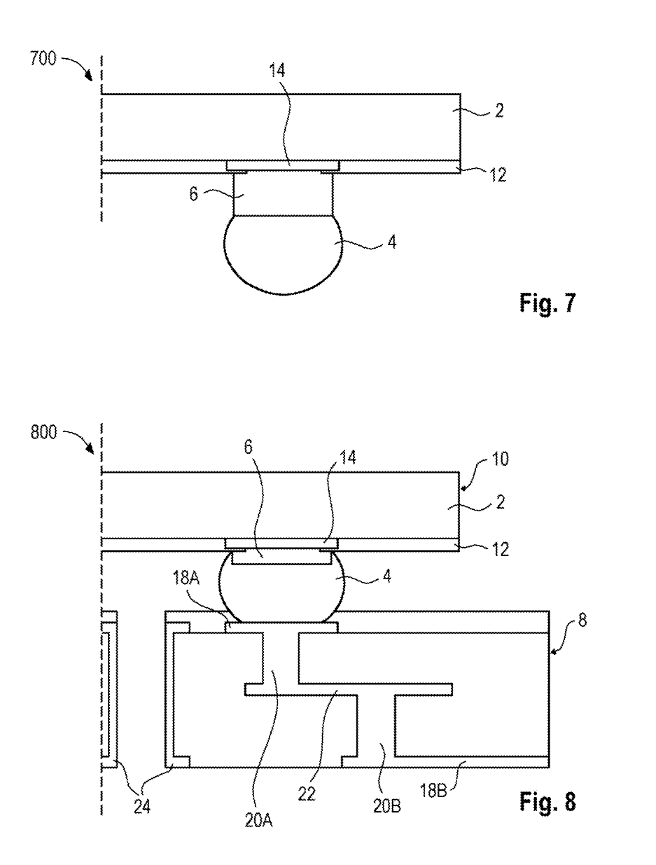

FIG. 7 schematically shows a lateral cross-sectional view of a semiconductor device 700 in accordance with the disclosure. Not all the components of the semiconductor device 700 are completely illustrated in the example in FIG. 7, this being indicated by a vertical dashed line on the left. The semiconductor device 700 can comprise for example the components of the semiconductor device 400 from FIG. 4. In addition, the semiconductor device 400 can comprise a metallization 6 in the form of a copper pillar, which can be configured in particular in a cylindrical fashion. The copper pillar 6 can be part of an electrical connection element in the form of a copper pillar bump that can be constructed from the copper pillar 6 and the solder material 4 arranged on the copper pillar. In the example in FIG. 7, the metallization or the copper pillar 6 can be produced from porous nanocrystalline copper or at least proportionally contain the latter. In a further example, the contact pad 14 can likewise comprise porous nanocrystalline copper.

FIG. 8 schematically shows a lateral cross-sectional view of a semiconductor device 800 in accordance with the disclosure. Not all the components of the semiconductor device 800 are completely illustrated in the example in FIG. 8, this being indicated by a vertical dashed line on the left. The semiconductor device 800 contains a semiconductor component 10 arranged on a circuit board (or a carrier) 8. In one example, the carrier 8 can be a carrier in a semiconductor component, e.g. in a ball grid array, as illustrated in FIG. 9. In a further example, the carrier 8 can be a circuit board on which a semiconductor component is arranged, as illustrated in FIG. 11. In the example in FIG. 8, the semiconductor component 10 can correspond for example to the semiconductor device 500 from FIG. 5.

On its upper and lower main surfaces, the circuit board 8 can have metallizations 18A and 18B, respectively, which are designed to be electrically contacted, for example by the electrical connection element 4 of the semiconductor component 10. Furthermore, the circuit board 8 has an internal redistribution structure, which can be constructed from one or a plurality of conductor tracks 22 and through contacts or via connections 20A, 20B. In the example in FIG. 8, only one conductor track 22 is illustrated, which can be electrically connected to the metallizations 18A, 18B on the main surfaces of the circuit board 8 by the via connections 20A, 20B. In further examples, the circuit board 8 can have further conductor tracks and via connections. The circuit board 8 furthermore has a via connection 24 that can be formed from metallizations on the sidewalls of a through-hole extending between the main surfaces of the circuit board 8. The via connection 24 can thus provide an electrical connection between the two main surfaces of the circuit board 8. In addition, an electrically insulating or an electrically conductive material (not illustrated) can be arranged in the through-hole.

A plurality of components or metallizations of the circuit board 8 can be produced from porous nanocrystalline copper or at least proportionally contain the latter. In this case, the porous copper can be contained in at least one of the metallizations 18A, 18B, the via connections 20A, 20B, the conductor track 22, the via connection 24. In a further example, in addition, one or more metallizations in the semiconductor component 10 can comprise porous nanocrystalline copper, as described above.

FIG. 9 schematically shows a lateral cross-sectional view of a semiconductor device 900 in accordance with the disclosure. The semiconductor device 900 constitutes a ball grid array (BGA) produced in accordance with a flip-chip technology. The semiconductor device 900 comprises a semiconductor chip 2 embedded into a mold material 32, first electrical connection elements 4A composed of a solder material for a flip-chip interconnection being arranged on the underside of said semiconductor chip. The semiconductor device 600 can further contain a carrier 26, which for example can correspond to the carrier 8 from FIG. 8 and contain identical components.

The semiconductor chip 2 can be soldered by its electrical connection elements 4A on metallizations 18A on the upper main surface of the carrier 26. In the example in FIG. 9, a capillary underfill may have been used to fit the semiconductor chip 2 on the carrier 26. The underfill material 28 used for this purpose may be optional and, in one example, may comprise or consist of an epoxy material. The semiconductor device 900 can furthermore comprise two electrical connection elements 4B composed of a solder material, which can be applied on the metallizations 18B on the lower main surface of the carrier 26. The second electrical connection elements 4B can be electrically coupled to the semiconductor chip 2 by way of the carrier 26.

In the example in FIG. 9, such metallizations of the semiconductor device 900 which adjoin the electrical connection elements 18A, 18B can be produced from porous nanocrystalline copper or at least proportionally contain the latter. Accordingly, by way of example, a plurality of the metallizations of the carrier 26 that have already been discussed in association with FIG. 8 can contain porous copper. As an alternative or in addition thereto, metallizations of the semiconductor chip 2 can contain porous copper, for example contact pads or underbump metallizations arranged on the underside of the semiconductor chip 2 (not illustrated).

FIG. 10 contains FIGS. 10A to 10C and schematically illustrates lateral cross-sectional views of semiconductor devices 1000A to 1000C in accordance with the disclosure which constitute wafer level packages.

The semiconductor device 1000A contains a semiconductor chip 2 embedded into a mold material 32. Electrical connection elements 4 are arranged on an underside of the semiconductor device 1000A, said electrical connection elements being connected to contact pads of the semiconductor chip 2 by way of a redistribution layer 16.

The semiconductor device 1000B contains a semiconductor chip 2 with electrical connection elements 4 arranged on contact pads of the semiconductor chip 2.

The semiconductor device 1000C contains a semiconductor chip 2, on the underside of which are arranged electrical connection elements 4 that are connected to contact pads of the semiconductor chip 2 by way of a redistribution layer 16.

One or more of the metalizations present in the semiconductor devices 1000A to 1000C can be produced from a porous nanocrystalline copper or at least proportionally contain the latter. By way of example, at least one of the contact pads, underbump metallizations (not illustrated) or metallizations of the redistribution layer 16 can comprise porous copper.

FIG. 11 schematically shows a lateral cross-sectional view of a semiconductor device 1100 in accordance with the disclosure. The semiconductor device 1100 comprises a semiconductor component 10, which can correspond to the semiconductor device 900 from FIG. 9. The semiconductor component 10 is arranged on a circuit board 30. The circuit board 30 can for example correspond to the circuit board 8 from FIG. 8 and have identical components. In the example in FIG. 11, an illustration of the internal construction of the circuit board 30 is dispensed with, and in this regard reference is made to FIG. 8. The semiconductor device 1100 can comprise one or more metallizations comprising porous nanocrystalline copper, such as have already been described for example in association with FIGS. 8 and 9.

FIG. 12 shows a qualitative temperature-time diagram for an exemplary heat treatment process such as can be used in the method in FIG. 3 for producing a metallization in a semiconductor device in accordance with the disclosure. In the diagram, the temperature used during the heat treatment is plotted against time. Firstly, the temperature rises to reach a first temperature, which is maintained for a first duration. Afterward, the temperature is increased to a second temperature and the temperature reached is maintained for a second duration. Then the temperature is increased to a third temperature and the temperature reached is maintained for a third duration. Finally, the temperature is increased to a fourth temperature and the temperature reached is maintained for a fourth duration. The heat treatment process is concluded by cooling the temperature to the initial temperature. The values for temperatures, temperature maintaining times and rates of the temperature increases, which values are specifically used for the heat treatment process qualitatively described, can or should be adapted e.g. in accordance with the method parameters of a preceding electrochemical deposition of copper, as is known by the person skilled in the art.

FIG. 13 shows a relative pore distribution of porous nanocrystalline copper such as can be used in one of the semiconductor devices in accordance with the disclosure, as a function of the pore size of the copper. The pore size of the porous nanocrystalline copper can be less than 0.79 μm². In this case, the pore size can be specified as the cross-sectional area of the cavity formed by the respective pore and can thus have the dimension of an area.

Within the meaning of the present description, the terms “connected”, “coupled”, “electrically connected” and/or “electrically coupled” need not necessarily mean that components must be directly connected or coupled to one another. Intervening components can be present between the “connected”, “coupled”, “electrically connected” or “electrically coupled” components.

Furthermore, the word “above” used for example with reference to a material layer which is formed “above” a surface of an object or is situated “above” said surface can be used in the present description in the sense that the material layer is arranged (for example formed, deposited, etc.) “directly on”, for example in direct contact with, the intended surface. In the present text, the word “above” used for example with reference to a material layer that is formed or arranged “above” a surface can also be used in the sense that the material layer is arranged (e.g. formed, deposited, etc.) “indirectly on” the intended surface, wherein for example one or more additional layers are situated between the intended surface and the material layer.

Insofar as the terms “have”, “contain”, “include”, “having” or variants thereof are used either in the detailed description or in the claims, these terms are intended to be inclusive in a manner similar to the term “comprise”. That is to say that, within the meaning of the present description, the terms “have”, “contain”, “include”, “having”, “comprise” and the like are open terms which indicate the presence of stated elements or features but do not exclude further elements or features. The articles “a/an” or “the” should be understood to include the plural meaning and also the singular meaning, provided that a different understanding is not clearly obvious from the context.

Furthermore, the word “exemplary” in the present text is used in the sense that it serves as an example, an instance or an illustration. One aspect or one design which is described as “exemplary” in the present text should not necessarily be understood as though it has advantages over other aspects or designs. Rather, the use of the word “exemplary” is intended to present concepts in a concrete manner. Within the meaning of this application, the term “or” does not mean an exclusive “or”, but rather an inclusive “or”. That is to say that, provided that nothing to the contrary is indicated or the context does not permit a different interpretation, “X uses A or B” means any of the natural inclusive permutations. That is to say that if X uses A, X uses B or X uses both A and B, then “X uses A or B” is satisfied in each of the cases mentioned above. Moreover, the articles “a/an” within the meaning of this application and the accompanying claims can generally be interpreted as “one or more”, unless it is expressly stated or clearly discernible from the context that only a singular is meant. Furthermore, at least one of A and B or the like generally means A or B or both A and B.

Devices and methods for producing devices are described in the present text. Observations made in connection with a device described can also apply to a corresponding method, and vice versa. If for example a specific component of a device is described, then a corresponding method for producing the device can contain a process for providing the component in a suitable manner, even if such a process is not explicitly described or illustrated in the figures. Moreover, the features of the various exemplary aspects as described in the present text can be combined with one another, unless expressly noted otherwise.

Although the disclosure has been shown and described with reference to one or more implementations, equivalent alterations and modifications which are based at least partly on the reading and understanding of this description and the accompanying drawings will be apparent to the person skilled in the art. The disclosure includes all such modifications and alterations and is restricted solely by the concept of the following claims. Especially with regard to the various functions performed by the above-described components (for example elements, resources, etc.), the intention is that, unless indicated otherwise, the terms used for describing such components correspond to any components which perform the specified function of the described component (which is functionally equivalent, for example), even if it is not structurally equivalent to the disclosed structure which performs the function of the exemplary implementations of the disclosure that are illustrated herein. Furthermore, even if a specific feature of the disclosure has been disclosed with reference to only one of various implementations, such a feature can be combined with one or more other features of the other implementations in a manner such as is desired and is advantageous for a given or specific application.

### LIST OF REFERENCE SIGNS

2 semiconductor chip
4 electrical connection element
6 metallization
8 carrier/circuit board
10 semiconductor device
12 passivation layer
14 contact pad
16 redistribution layer
18 metallization
20 via connection
22 conductor track
24 via connection
26 carrier
28 underfill material
30 circuit board
32 mold material

What is claimed is:

1. A semiconductor device, comprising:
a semiconductor chip;
an electrical connection element that electrically connects the semiconductor device to a carrier; and
a metallization adjoining the electrical connection element, wherein the metallization contains porous nanocrystalline copper and wherein the porous nanocrystalline copper contains portions of organic acids.

2. The semiconductor device as claimed in claim 1, wherein the porosity of the porous nanocrystalline copper lies in a range of 5% to 20%.

3. The semiconductor device as claimed in claim 1, wherein a mean pore diameter of the porous nanocrystalline copper is less than 1 μm.

4. The semiconductor device as claimed in claim 1, wherein the metallization has a closed-porous region extending at a surface of the metallization.

5. The semiconductor device as claimed in claim 1, wherein the metallization is part of a contact pad of the semiconductor chip and the electrical connection element is arranged on the contact pad.

6. The semiconductor device as claimed in claim 1, wherein the metallization is part of an underbump metallization arranged between a contact pad of the semiconductor chip and the electrical connection element.

7. The semiconductor device as claimed in claim 1, wherein the metallization is part of a copper pillar arranged on the semiconductor chip, the copper pillar being arranged between a contact pad of the semiconductor chip and the electrical connection element.

8. The semiconductor device as claimed in claim 1, wherein the metallization is part of a conductor track of a redistribution layer arranged on the semiconductor chip, wherein the redistribution layer is electrically connected to the electrical connection element.

9. The semiconductor device as claimed in claim 1, wherein the carrier has a first main surface and a second main surface situated opposite the first main surface, wherein the semiconductor chip is arranged on the first main surface of the carrier and the electrical connection element is arranged on the second main surface of the carrier.

10. The semiconductor device as claimed in claim 9, wherein the metallization is part of a conductor track of a redistribution layer within the carrier, wherein the redistribution layer is electrically connected to the electrical connection element.

11. The semiconductor device as claimed in claim 9, wherein the metallization is part of a plurality of metallization planes of a redistribution layer within the carrier.

12. The semiconductor device as claimed in claim 9, wherein the metallization is part of a conductor track on one of the first main surface or the second main surface of the carrier, wherein the conductor track is electrically connected to the electrical connection element.

13. The semiconductor device as claimed in claim 9, wherein the metallization is part of a via connection within the carrier.

14. A method for producing a metallization in a semiconductor device, the method comprising:
depositing copper by a electrochemical deposition; and
applying a heat treatment to the deposited copper, as a result of which a metallization composed of porous nanocrystalline copper is formed.

15. The method as claimed in claim 14, wherein the electrochemical deposition uses an electrolyte comprised of copper sulfate, ammonium sulfate, and citric acid.

16. The method as claimed in claim 14, wherein the electrochemical deposition uses an electrolyte having a pH of 1.8 to 2.5.

17. The method as claimed in claim 14, wherein a current density used for the electrochemical deposition lies in a range from 0.5 A/dm² to 6 A/dm².

18. A semiconductor device comprising:
a circuit board;
a semiconductor component arranged on the circuit board;
an electrical connection element, wherein the electrical connection element is electrically connected to the circuit board; and
a metallization of the circuit board adjoining the electrical connection element, wherein the metallization contains porous nanocrystalline copper and wherein the porous nanocrystalline copper contains portions of organic acids.

19. The semiconductor device as claimed in claim 18, wherein the metallization is part of a conductor track of a redistribution layer within the circuit board or part of a via connection of the redistribution layer within the circuit board, wherein the redistribution layer is electrically connected to the electrical connection element.

20. A method for producing an electrical connection between a semiconductor device and a carrier, the method comprising:
depositing copper by a electrochemical deposition;
applying a heat treatment to the deposited copper, as a result of which a metallization composed of porous nanocrystalline copper is formed; and
electrically connecting the semiconductor device to the carrier by way of an electrical connection element, wherein the metallization composed of the porous nanocrystalline copper directly adjoins the electrical connection element.
